(19) United States
(12) Patent Application Publication
(10) Pub. No.: US 2011/0195176 A1
(43) Pub. Date: Aug. 11, 2011

(54) Method of Manufacturing a Display

(75) Inventors: Paul Wallace, Hertfordshire (GB); Simon Goddard, Cambridgeshire (GB)

(73) Assignee: CAMBRIDGE DISPLAY TECHNOLOGY LIMITED, Cambridgeshire (GB)

(21) Appl. No.: 13/057,693

(22) PCT Filed: Aug. 20, 2009
(86) PCT No.: PCT/GB2009/002037

§ 371 Date: Apr. 28, 2011

(30) Foreign Application Priority Data
Aug. 22, 2008 (GB) 0815473.4

(51) Int. Cl. B05D 7/24; C09D 11/10; B05D 5/12; B05D 5/06; B05D 1/02

(52) U.S. Cl. 427/58; 252/500

(57) ABSTRACT

A method for the manufacture of an organic light-emissive display comprises: providing a substrate comprising a first electrode layer and a bank structure defining a plurality of wells; depositing a conductive organic layer over the first electrode; depositing an organic light-emissive layer over the conductive organic layer; and depositing a second electrode over the organic light-emissive layer, wherein the conductive organic layer is deposited by ink jet printing a composition comprising poly(ethylene dioxythiophene) (PEDOT) doped with a polyanion, wherein the polyanion has a molecular weight of equal to or less than 30 kDa measured relative to polystyrene molecular weight standards using gel-permeation chromatography, the viscosity of the composition being equal to or less than 10 mPa·s, and the solids content of the composition being equal to or less than 5 wt % based on the volume of the composition. The composition may include an optional solvent or other additive.

### FIELD OF INVENTION

This invention relates to methods of manufacturing opto-electrical devices such as an organic light emissive display, and compositions for ink jet printing said opto-electrical devices.

### BACKGROUND OF INVENTION

One class of opto-electrical devices is that using an organic material for light emission (or detection in the case of photovoltaic cells and the like). The basic structure of these devices is a light emissive organic layer, for instance a film of a poly (p-phenylenevinylene) (“PPV”) or polyfluorene, sandwiched between a cathode for injecting negative charge carriers (electrons) and an anode for injecting positive charge carriers (holes) into the organic layer. The electrons and holes combine in the organic layer generating photons. In WO90/13148 the organic light-emissive material is a polymer. In U.S. Pat. No. 4,539,507 the organic light-emissive material is of the class known as small molecule materials, such as (8-hydroxyquinoline) aluminium (“Alq3”). In a practical device one of the electrodes is transparent, to allow the photons to escape the device.

A typical organic light-emissive device (“OLED”) is fabricated on a glass or plastic substrate coated with a transparent anode such as indium-tin-oxide (“ITO”). A layer of a thin film of at least one electroluminescent organic material covers the first electrode. Finally, a cathode covers the layer of electroluminescent organic material. The cathode is typically a metal or alloy and may comprise a single layer, such as aluminium, or a plurality of layers such as calcium and aluminium.

In operation, holes are injected into the device through the anode and electrons are injected into the device through the cathode. The holes and electrons combine in the organic electroluminescent layer to form an exciton which then undergoes radiative decay to give light (in light detecting devices this process essentially runs in reverse).

These devices have great potential for displays. However, there are several significant problems. One is to make the device efficient, particularly as measured by its external power efficiency and its external quantum efficiency. Another is to optimise (e.g. to reduce) the voltage at which peak efficiency is obtained. Another is to stabilise the voltage characteristics of the device over time. Another is to increase the lifetime of the device.

To this end, numerous modifications have been made to the basic device structure described above in order to solve one or more of these problems.

One such modification is the provision of a layer of conductive polymer between the light-emissive organic layer and one of the electrodes. It has been found that the provision of such a conductive polymer layer can improve the turn-on voltage, the brightness of the device at low voltage, the efficiency, the lifetime and the stability of the device. In order to achieve these benefits these conductive polymer layers typically may have a sheet resistance less than 10⁶ Ohms/square, the conductivity being controllable by doping of the polymer layer. It may be advantageous in some device arrangements not to have too high a conductivity. For example, if a plurality of electrodes are provided in a device but only one continuous layer of conductive polymer extending over all the electrodes, then too high a conductivity can lead to lateral conduction (known as “cross-talk) and shorting between electrodes.

The conductive polymer layer may also be selected to have a suitable workfunction so as to aid in hole or electron injection and/or to block holes or electrons. There are thus two key electrical features: the overall conductivity of the conductive polymer composition; and the workfunction of the conductive polymer composition. The stability of the composition and reactivity with other components in a device will also be critical in providing an acceptable lifetime for a practical device. The processability of the composition will be critical for ease of manufacture.

Conductive polymer formulations are discussed in the applicant's earlier application GB-A-0428444.4. There is an ongoing need to optimise the organic formulations used in these devices both in the light emitting layer and the conductive polymer layer.

OLEDs can provide a particularly advantageous form of electro-optic display. They are bright, colourful, fast-switching, provide a wide viewing angle and are easy and cheap to fabricate on a variety of substrates. Organic (which here includes organometallic) LEDs may be fabricated using either polymers or small molecules in a range of colours (or in multi-coloured displays), depending upon the materials used. As previously described, a typical OLED device comprises two layers of organic material, one of which is a layer of light emitting material such as a light emitting polymer (LEP), oligomer or a light emitting low molecular weight material, and the other of which is a conductive polymer layer, for example a layer of a hole transporting material such as a polythiophene derivative or a polyaniline derivative.

Organic LEDs may be deposited on a substrate in a matrix of pixels to form a single or multi-colour pixellated display. A multicoloured display may be constructed using groups of red, green, and blue emitting pixels. So-called active matrix displays have a memory element, typically a storage capacitor and a transistor, associated with each pixel whilst passive matrix displays have no such memory element and instead are repetitively scanned to give the impression of a steady image.

FIG. 1 shows a vertical cross section through an example of an OLED device 100. In an active matrix display, part of the area of a pixel is occupied by associated drive circuitry (not shown in FIG. 1). The structure of the device is somewhat simplified for the purposes of illustration.

The OLED 100 comprises a substrate 102, typically 0.7 mm or 1.1 mm glass but optionally clear plastic, on which an anode layer 106 has been deposited. The anode layer typically comprises around 150 nm thickness of ITO (indium tin oxide), over which is provided a metal contact layer, typically around 500 nm of aluminium, sometimes referred to as anode metal. Glass substrates coated with ITO and contact metal may be purchased from Corning, USA. The contact metal (and optionally the ITO) is patterned as desired so that it does not obscure the display, by a conventional process of photolithography followed by etching.

A substantially transparent hole transport layer 108a is provided over the anode metal, followed by an electroluminescent layer 108b. Banks 112 may be formed on the substrate, for example from positive or negative photoresist material, to define wells 114 into which these active organic layers may be selectively deposited, for example by a droplet deposition or inkjet printing technique. The wells thus define light emitting areas or pixels of the display. As an alternative to wells, the photoresist may be patterned to form other types of openings into which the active organic layers may be selectively deposited. In particular, the photoresist may be patterned to form channels which, unlike wells, extend over a plurality of pixels and which may be closed or open at the channel ends.

A cathode layer 110 is then applied by, say, physical vapour deposition. The cathode layer typically comprises a low work function metal such as calcium or barium covered with a thicker, capping layer of aluminium and optionally including an additional layer immediately adjacent the electroluminescent layer, such as a layer of lithium fluoride, for improved electron energy level matching. The cathode may be transparent. This is particularly preferred for active matrix devices wherein emission through the substrate is partially blocked by drive circuitry located underneath the emissive pixels. In the case of a transparent cathode device, it will be appreciated that the anode is not necessarily transparent. In the case of passive matrix displays, mutual electrical isolation of cathode lines may achieved through the use of cathode separators (element 302 of FIG. 3b). Typically a number of displays are fabricated on a single substrate and at the end of the fabrication process the substrate is scribed, and the displays separated. An encapsulant such as a glass sheet or a metal can is utilized to inhibit oxidation and moisture ingress.

Organic LEDs of this general type may be fabricated using a range of materials including polymers, dendrimers, and so-called small molecules, to emit over a range of wavelengths at varying drive voltages and efficiencies. Examples of polymer-based OLED materials are described in WO90/13148, WO95/06400 and WO99/48160; examples of dendrimer-based materials are described in WO 99/21935 and WO 02/067343; and examples of small molecule OLED materials are described in U.S. Pat. No. 4,539,507. The aforementioned polymers, dendrimers and small molecules emit light by radiative decay of singlet excitons (fluorescence). However, up to 75% of excitons are triplet excitons which normally undergo non-radiative decay. Electroluminescence by radiative decay of triplet excitons (phosphorescence) is disclosed in, for example, “Very high-efficiency green organic light-emitting devices based on electrophosphorescence” M. A. Baldo, S. Lamansky, P. E. Burrows, M. E. Thompson, and S. R. Forrest Applied Physics Letters, Vol. 75(1) pp. 4-6, Jul. 5, 1999″. In the case of a polymer-based OLED, layers 108 comprise a hole injection layer 108a and a light emitting polymer (LEP) electroluminescent layer 108b. The electroluminescent layer may comprise, for example, around 70 nm (dry) thickness of PPV (poly(p-phenylenevinylene)) and the hole injection layer, which helps match the hole energy levels of the anode layer and of the electroluminescent layer, may comprise, for example, around 50-200 nm, preferably around 150 nm (dry) thickness of PEDOT:PSS (polystyrene-sulphonate-doped polyethylene-dioxythiophene).

FIG. 2 shows a view from above (that is, not through the substrate) of a portion of a three-colour active matrix pixellated OLED display 200 after deposition of one of the active colour layers. The figure shows an array of banks 112 and wells 114 defining pixels of the display.

FIG. 3a shows a view from above of a substrate 300 for inkjet printing a passive matrix OLED display. FIG. 3b shows a cross-section through the substrate of FIG. 3a along line Y-Y′.

Referring to FIGS. 3a and 3b, the substrate is provided with a plurality of cathode undercut separators 302 to separate adjacent cathode lines (which will be deposited in regions 304). A plurality of wells 308 is defined by banks 310, constructed around the perimeter of each well 308 and leaving an anode layer 306 exposed at the base of the well. The edges or faces of the banks are tapered onto the surface of the substrate as shown, heretofore at an angle of between 10 and 40 degrees. The banks present a hydrophobic surface in order that they are not wetted by the solution of deposited organic material and thus assist in containing the deposited material within a well. This is achieved by treatment of a bank material such as polyimide with an O₂/CF₄ plasma as disclosed in EP 0989778. Alternatively, the plasma treatment step may be avoided by use of a fluorinated material such as a fluorinated polyimide as disclosed in WO 03/083960.

As previously mentioned, the bank and separator structures may be formed from resist material, for example using a positive (or negative) resist for the banks and a negative (or positive) resist for the separators; both these resists may be based upon polyimide and spin coated onto the substrate, or a fluorinated or fluorinated-like photoresist may be employed. In the example shown the cathode separators are around 5 μm in height and approximately 20 μm wide. Banks are generally between 20 μm and 100 μm in width and in the example shown have a 4 μm taper at each edge (so that the banks are around 1 μm in height). The pixels of FIG. 3a are approximately 300 μm square but, as described later, the size of a pixel can vary considerably, depending upon the intended application.

The deposition of material for organic light emitting diodes (OLEDs) using ink jet printing techniques is described in a number of documents including, for example: Y. Yang, “Review of Recent Progress on Polymer Electroluminescent Devices,” SPIE Photonics West: Optoelectronics '98, Conf. 3279, San Jose, January, 1998; EP 0 880 303; and “Ink-Jet Printing of Polymer Light-Emitting Devices”, Paul C. Duineveld, Margreet M. de Kok, Michael Buechel, Aad H. Sempel, Kees A. H. Mutsaers, Peter van de Weijer, Ivo G. J. Camps, Ton J. M. van den Biggelaar, Jan-Eric J. M. Rubingh and Eliav I. Haskal, Organic Light-Emitting Materials and Devices V, Zakya H. Kafafi, Editor, Proceedings of SPIE Vol. 4464 (2002). Ink jet techniques can be used to deposit materials for both small molecule and polymer LEDs.

A volatile solvent is generally employed to deposit a molecular electronic material, with 0.5% to 4% dissolved material. This can take anything between a few seconds and a few minutes to dry and results in a relatively thin film in comparison with the initial “ink” volume. Often multiple drops are deposited, preferably before drying begins, to provide sufficient thickness of dry material. Typical solvents which have been used include cyclohexylbenzene and alkylated benzenes, in particular toluene or xylene; others are described in WO 00/59267, WO 01/16251 and WO 02/18513; a solvent comprising a blend of these may also be employed. Precision ink jet printers such as machines from Litrex Corporation of California, USA are used; suitable print heads are available from Xaar of Cambridge, UK and Spectra, Inc. of NH, USA. Some particularly advantageous print strategies are described in the applicant's UK patent application number 0227778.8 filed on 28 Nov. 2002.

The feasibility of using ink jet printing to define hole conduction and electroluminescent layers in OLED display has been well demonstrated. The particular motivation for ink jet printing has been driven by the prospect of developing scalable and adaptable manufacturing processes, enabling large substrate sizes to be processed, without the requirement for expensive product specific tooling.

Recent years have seen an increasing activity in the development of ink jet printing for depositing electronic materials. In particular there have been demonstrations of ink jet printing of both hole conduction (HC) and electroluminescent (EL) layers of OLED devices by more than a dozen display manufacturers.

Ink jet printing of the hole conduction/hole injection layer typically involves using a composition which comprises PEDOT:PSS. Such compositions are sold commercially by each H C Starck of Leverkusen, Germany under the trade mark Baytron P. In aqueous solution, PEDOT is relatively insoluble whereas PSS is relatively soluble. Additional PSS may be added to the commercially-available compositions so as to increase their electrical film resistivity. For example, in WO2006/123167, compositions for ink jet printing are provided which comprise an electroluminescent or charge transporting material and a high boiling point solvent. These compositions comprise 30% glycerol and 69% water, with a 1% solids content of a 30 or 40:1 PSS:PEDOT formulation. Such high PSS levels, however, tend to affect adversely the lifetime of the devices made and so it is preferred to use lower amounts of PSS. A drawback with ink jetting compositions of this type is that the solids content is relatively low and cannot be significantly increased. Compositions having a high solids content tend to have a high viscosity and this makes it difficult or impossible for these compositions to be deposited using ink jet printing. A problem with ink jet printing compositions of relatively low solids content is that it is difficult to achieve a layer of sufficient thickness for use in an electroluminescent device. In practice, if such a device is to be fabricated by ink jet printing, the charge transporting organic layer has to be deposited in more than one pass of the printer head. This can have a dramatic effect on the quality of the layer because deposition in multiple passes tends to result in an uneven layer. In turn, this gives rise to poor device performance because unevenness in the layer of charge transporting organic material gives rise to unevenness in the organic light-emissive layer thereon.

A need therefore exists for improved compositions for ink jet printing opto-electrical devices which do not suffer from the drawbacks of the prior art.

### SUMMARY OF THE INVENTION

According to a first aspect, the present invention provides a composition for ink jet printing an opto-electrical device, which composition comprises a charge transporting organic material which comprises poly(ethylene dioxythiophene) (PEDOT) doped with a polyanion, wherein the polyanion has a molecular weight of less than 70 kDa measured relative to polystyrene molecular weight standards using gel-permeation chromatography.

The invention is described further hereinafter with respect to PEDT:PSS, however it will be appreciated that any suitable polyanion may be used in place of PSS.

It has been found that the use of PSS with a molecular weight which is lower than the conventional, commercially-available PSS may be used in the charge transporting organic layer and has the effect of reducing viscosity of the composition for ink jet printing without adverse effect on device performance. This allows the composition to be deposited by ink jet printing at a higher solids content than hitherto envisaged. In this way, the need for multiple passes of the print head is avoided.

The present applicant has found that the problem of film non-uniformity in PEDOT is very important to device performance, especially EL device performance. The device performance may not be directly affected significantly by the thickness of the PEDOT film. However, the uniformity of the PEDOT film affects the uniformity of the overlying electroluminescent layer. The EL layer is very sensitive to changes in thickness. Accordingly, the present applicant has found that it is paramount that uniform films of PEDOT profiles are achieved in order to achieve uniform EL profiles.

PSS in commercially-available PEDOT:PSS tends to have a molecular weight of the order of 500 kDa. In contrast, PSS used according to the present invention has a molecular weight of less than 70 kDa, preferably less than 40 kDa and most preferably less than 30 kDa. In the examples described herein, the PSS molecular weight is approximately 27.3 kDa.

The quantity of PSS counterion present in a PEDOT:counterion composition is at least sufficient to balance the charge on PEDOT, and the PEDOT:counterion ratio may be in the range 1:2.5 to 1:18, more preferably in the range of from 1:6 to 1:10. The PSS having a molecular weight of less than 40 kDa may be used alone or in a mixture with PSS of higher molecular weight. For example, a 1:6 PEDOT:PSS composition with a PSS molecular weight of 70 kDa could incorporate an amount of PSS having a molecular weight of less than 40 kDa to give rise to a composition with an overall weight ratio of PEDOT:PSS of 1:10

The lateral resistivity of the film is usually 10 to 5000 and preferably no more than about 1000 ohm·cm.

The composition of the present invention further comprises a solvent. The solvent, which may be one or more solvents which are preferable miscible with each other, may dissolve the organic material or the solvent and organic material may together form a dispersion. For example, an aqueous composition of PEDOT/PSS is in the form of a dispersion. Preferably, the solvent is an aqueous solvent which typically includes water and one or more organic solvents. WO2006/123167 provides examples of solvents usable in the present invention. According to this arrangement, a high boiling point solvent having a boiling point higher than water is provided. The provision of the high boiling point solvent increases the drying time of the composition which leads to a greater uniformity of drying in a more symmetric film formation.

Preferably, the high boiling point solvent is present in the composition in a proportion between 10% and 50%, 20% and 40% or approximately 30% by volume. Preferably, the boiling point of the solvent is between 110 and 400° C., 150 and 250° C., or 170 and 230° C.

The high boiling point solvent may comprise one or more of ethylene glycol, glycerol, diethylene glycol, propylene glycol, butane-1,4-diol, propane-1,3-diol, dimethyl-2-imidazolidinone, N-methyl-2-pyrrolidone and dimethyl sulphoxide. These solvent components may be supplied alone or in a blend. The high boiling point solvent is preferably a polyol such as ethylene glycol, diethylene glycol or glycerol.

For small pixels a higher solid content is generally used. For larger pixels a lower solid content is used. For larger pixels, the concentration of the composition is reduced to get good film forming properties. Typical solids content ranges from 0.1 to 5 wt %, preferably 0.4 to 2.5 wt %, based on the volume of the composition.

If the solvent is very viscous then it can become difficult to ink jet print the composition. If the viscosity of the composition becomes too high then it will not be suitable for ink jet printing without heating the print head. Embodiments of the present invention are preferably of a viscosity such that heating of the print head is not required in order to ink jet print the compositions. It is preferred that the viscosity of the composition is no more than 12 mPa·s and more preferably no more than 10 mPa·s.

Furthermore, if the contact angle between the solvent and the material of the banks is too large, then the banks may not be sufficiently wetted. Conversely, if the contact angle between the solvent and the banks is too small, then the banks may not contain the composition leading to flooding of the wells.

Thus, selecting an arbitrary high boiling point solvent can alter the wetting characteristics of the composition. For example, if the contact angle between the composition and the bank is too large then on drying the film has thin edges resulting in non-uniform emission. Alternatively, if the contact angle between the composition and the bank is too small then the well will flood. With such an arrangement, on drying, conductive/semi-conductive organic material will be deposited over the bank structure leading to problems of shorting.

Preferably, the composition should have a contact angle with the bank such that it wets the bank but does not flood out of the well. With this arrangement, on drying a coffee ring effect occurs resulting in a thickening of the edges. A more uniform film morphology results producing a more uniform emission in the finished device.

If the contact angle between the electroluminescent material and the conductive material is too high then the conductive material will not be sufficiently wetted by the electroluminescent material.

One solution to the problem of flooding is to select a high boiling point solvent which has a sufficient contact angle such that it is adequately contained in the wells. Conversely, one solution to the problem of insufficient wetting of the banks is to select a high boiling point solvent which does not have a high contact angle with the material of the base of the well and does not have a contact angle with the banks which is too high.

The problem of insufficient wetting or flooding can be controlled by the addition of a suitable additive to modify the contact angle such that the well is sufficiently wetted without flooding. The provision of such a additive can also produce flatter film morphologies.

A surfactant may be added to the composition to increase the ability of the composition to wet the well. Suitable surfactants include 2-butoxyethanol.

In the case where the composition of the invention is inkjet printed, it preferably has a surface tension of at least 35 mN/m to avoid leakage of the composition from the inkjet print head.

According to another aspect of the present invention there is provided use of a composition, as described herein, for ink jetting a layer in the manufacture of an opto-electrical device.

According to another aspect of the present invention there is provided an opto-electrical device formed using the compositions described herein.

According to yet another aspect of the present invention there is provided a process for the manufacture of an organic light-emissive display comprising: providing a substrate comprising a first electrode layer and a bank structure defining a plurality of wells; depositing a conductive organic layer over the first electrode; depositing an organic light-emissive layer over the conductive organic layer; and depositing a second electrode over the organic light-emissive layer, wherein the conductive organic layer is deposited by ink jet printing a composition as described herein into the plurality of wells.

### BRIEF SUMMARY OF THE DRAWINGS

Embodiments of the present invention will now be described, by way of example only, with reference to the accompanying drawings in which:

FIG. 1 shows a vertical cross section through an example of an OLED device;

FIG. 2 shows a view from above of a portion of a three colour pixelated OLED display;

FIGS. 3a and 3b show a view from above and a cross-sectional view respectively of a passive matrix OLED display; and

FIG. 4a shows the jetting directionality of a composition according to the present invention at 2 kHz

FIG. 4b shows the jetting directionality of a of a comparative composition at 2 kHz

### DETAILED DESCRIPTION OF PREFERRED EMBODIMENTS

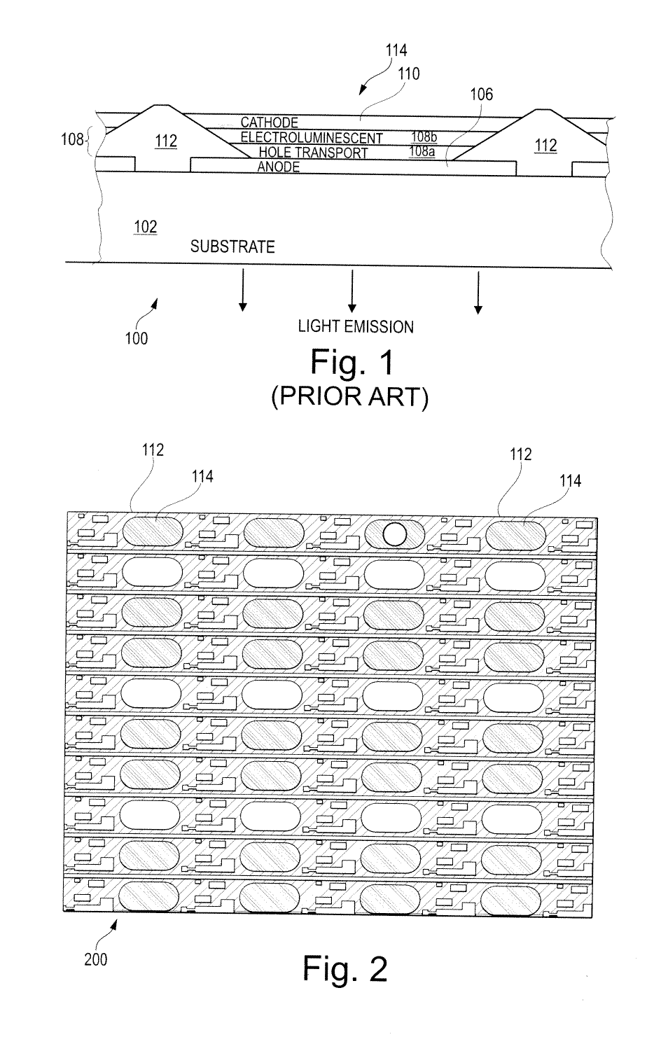

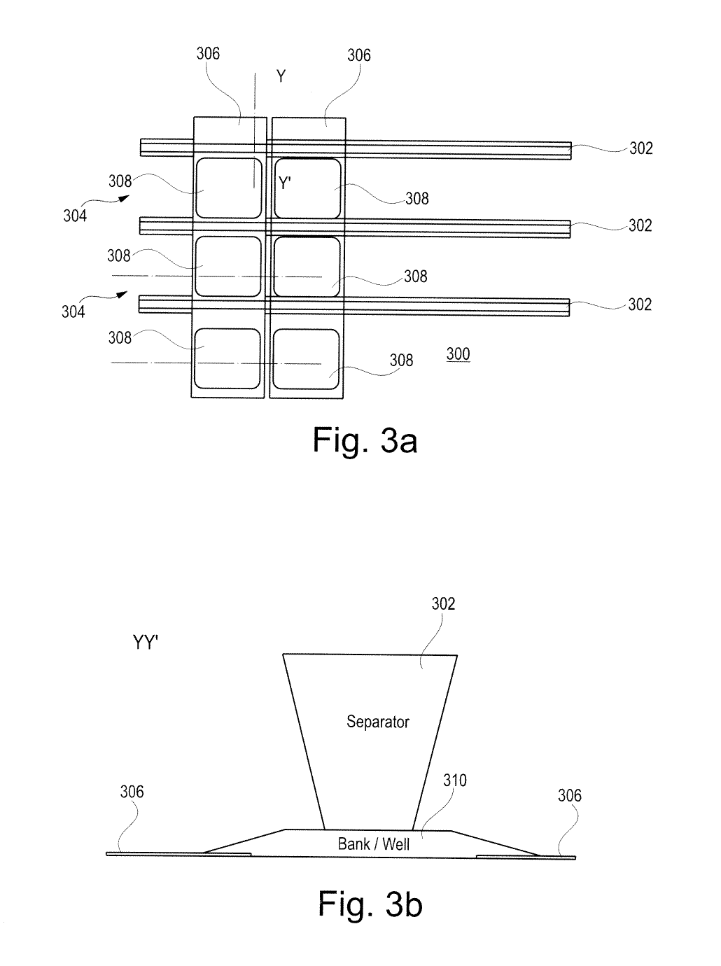

The general device architecture is illustrated in FIG. 1 and has been described above.

The device is preferably encapsulated with an encapsulant (not shown) to prevent ingress of moisture and oxygen. Suitable encapsulants include a sheet of glass, films having suitable barrier properties such as alternating stacks of polymer and dielectric as disclosed in, for example, WO 01/81649 or an airtight container as disclosed in, for example, WO 01/19142. A getter material for absorption of any atmospheric moisture and/or oxygen that may permeate through the substrate or encapsulant may be disposed between the substrate and the encapsulant.

Suitable polymers for charge transport and emission may comprise a first repeat unit selected from arylene repeat units, in particular: 1,4-phenylene repeat units as disclosed in J. Appl. Phys. 1996, 79, 934; fluorene repeat units as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer.

Particularly preferred polymers comprise optionally substituted, 2,7-linked fluorenes, most preferably first repeat units of formula:

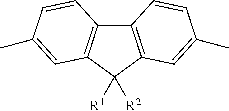

wherein R¹ and R² are independently selected from hydrogen or optionally substituted alkyl, alkoxy, aryl, arylalkyl, heteroaryl and heteroarylalkyl. More preferably, at least one of R¹ and R² comprises an optionally substituted C₄-C₂₀ alkyl or aryl group.

A polymer comprising the first repeat unit may provide one or more of the functions of hole transport, electron transport and emission depending on which layer of the device it is used in and the nature of co-repeat units.

Electroluminescent copolymers may comprise an electroluminescent region and at least one of a hole transporting region and an electron transporting region as disclosed in, for example, WO 00/55927 and U.S. Pat. No. 6,353,083. If only one of a hole transporting region and electron transporting region is provided then the electroluminescent region may also provide the other of hole transport and electron transport functionality.

The different regions within such a polymer may be provided along the polymer backbone, as per U.S. Pat. No. 6,353,083, or as groups pendant from the polymer backbone as per WO 01/62869.

A single polymer or a plurality of polymers may be deposited from solution to form layer 5. Suitable solvents for polyarylenes, in particular polyfluorenes, include mono- or poly-alkylbenzenes such as toluene and xylene. Particularly preferred solution deposition techniques are spin-coating and inkjet printing.

Inkjet printing is particularly suitable for high information content displays, in particular full colour displays. Inkjet printing of OLEDs is described in, for example, EP 0880303.

In some cases, distinct layers of the device may be formed by different methods, for example a hole injection and/or transport layer may be formed by spin-coating and an emissive layer may be deposited by inkjet printing.

If multiple layers of the device are formed by solution processing then the skilled person will be aware of techniques to prevent intermixing of adjacent layers, for example by crosslinking of one layer before deposition of a subsequent layer or selection of materials for adjacent layers such that the material from which the first of these layers is formed is not soluble in the solvent used to deposit the second layer.

Numerous hosts are described in the prior art including “small molecule” hosts such as 4,4′-bis(carbazol-9-yl)biphenyl), known as CBP, and (4,4′,4″-tris(carbazol-9-yl)triphenylamine), known as TCTA, disclosed in Ikai et al. (Appl. Phys. Lett., 79 no. 2, 2001, 156); and triarylamines such as tris-4-(N-3-methylphenyl-N-phenyl)phenylamine, known as MTDATA. Polymers are also known as hosts, in particular homopolymers such as poly(vinyl carbazole) disclosed in, for example, Appl. Phys. Lett. 2000, 77(15), 2280; polyfluorenes in Synth. Met. 2001, 116, 379, Phys. Rev. B 2001, 63, 235206 and Appl. Phys. Lett. 2003, 82(7), 1006; poly[4-(N-4-vinylbenzyloxyethyl, N-methylamino)-N-(2,5-di-tert-butylphenylnapthalimide] in Adv. Mater. 1999, 11(4), 285; and poly(para-phenylenes) in J. Mater. Chem. 2003, 13, 50-55. Copolymers are also known as hosts.

The emissive species may be metal complexes. The metal complexes may comprise optionally substituted complexes of formula (22):

ML¹_{q}L²ᵣL³ₛ (22)

wherein M is a metal; each of L¹, L² and L³ is a coordinating group; q is an integer; r and s are each independently 0 or an integer; and the sum of (a. q)+(b. r)+(c.s) is equal to the number of coordination sites available on M, wherein a is the number of coordination sites on L¹, b is the number of coordination sites on L² and c is the number of coordination sites on L³.

Heavy elements M induce strong spin-orbit coupling to allow rapid intersystem crossing and emission from triplet states (phosphorescence). Suitable heavy metals M include:

lanthanide metals such as cerium, samarium, europium, terbium, dysprosium, thulium, erbium and neodymium; and

d-block metals, in particular those in rows 2 and 3 i.e. elements 39 to 48 and 72 to 80, in particular ruthenium, rhodium, pallaidum, rhenium, osmium, iridium, platinum and gold.

Suitable coordinating groups for the f-block metals include oxygen or nitrogen donor systems such as carboxylic acids, 1,3-diketonates, hydroxy carboxylic acids, Schiff bases including acyl phenols and iminoacyl groups. As is known, luminescent lanthanide metal complexes require sensitizing group(s) which have the triplet excited energy level higher than the first excited state of the metal ion. Emission is from an f-f transition of the metal and so the emission colour is determined by the choice of the metal. The sharp emission is generally narrow, resulting in a pure colour emission useful for display applications.

The d-block metals form organometallic complexes with carbon or nitrogen donors such as porphyrin or bidentate ligands of formula (VI):

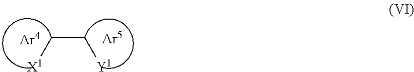

wherein Ar⁴ and Ar⁵ may be the same or different and are independently selected from optionally substituted aryl or heteroaryl; X¹ and Y¹ may be the same or different and are independently selected from carbon or nitrogen; and Ar⁴ and Ar⁵ may be fused together. Ligands wherein X¹ is carbon and Y¹ is nitrogen are particularly preferred.

Examples of bidentate ligands are illustrated below:

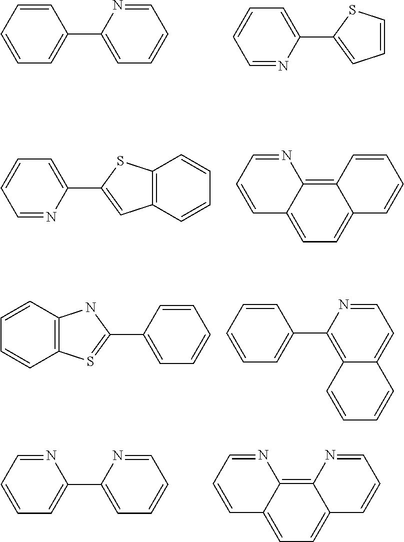

Each of Ar⁴ and Ar⁵ may carry one or more substituents. Particularly preferred substituents include fluorine or trifluoromethyl which may be used to blue-shift the emission of the complex as disclosed in WO 02/45466, WO 02/44189, US 2002-117662 and US 2002-182441; alkyl or alkoxy groups as disclosed in JP 2002-324679; carbazole which may be used to assist hole transport to the complex when used as an emissive material as disclosed in WO 02/81448; bromine, chlorine or iodine which can serve to functionalise the ligand for attachment of further groups as disclosed in WO 02/68435 and EP 1245659; and dendrons which may be used to obtain or enhance solution processability of the metal complex as disclosed in WO 02/66552.

Other ligands suitable for use with d-block elements include diketonates, in particular acetylacetonate (acac); triarylphosphines and pyridine, each of which may be substituted.

Main group metal complexes show ligand based, or charge transfer emission. For these complexes, the emission colour is determined by the choice of ligand as well as the metal.

The host material and metal complex may be combined in the form of a physical blend. Alternatively, the metal complex may be chemically bound to the host material. In the case of a polymeric host, the metal complex may be chemically bound as a substituent attached to the polymer backbone, incorporated as a repeat unit in the polymer backbone or provided as an end-group of the polymer as disclosed in, for example, EP 1245659, WO 02/31896, WO 03/18653 and WO 03/22908.

A wide range of fluorescent low molecular weight metal complexes are known and have been demonstrated in organic light emitting devices [see, e.g., Macromol. Sym. 125 (1997) 1-48, U.S. Pat. No. 5,150,006, U.S. Pat. No. 6,083,634 and U.S. Pat. No. 5,432,014]. Suitable ligands for di or trivalent metals include: oxinoids, e.g. with oxygen-nitrogen or oxygen-oxygen donating atoms, generally a ring nitrogen atom with a substituent oxygen atom, or a substituent nitrogen atom or oxygen atom with a substituent oxygen atom such as 8-hydroxyquinolate and hydroxyquinoxalinol-10-hydroxybenzo (h) quinolinato (II), benzazoles (III), schiff bases, azoindoles, chromone derivatives, 3-hydroxyflavone, and carboxylic acids such as salicylato amino carboxylates and ester carboxylates. Optional substituents include halogen, alkyl, alkoxy, haloalkyl, cyano, amino, amido, sulfonyl, carbonyl, aryl or heteroaryl on the (hetero) aromatic rings which may modify the emission colour.

### Composition Formation Procedure

An exemplary composition according to the present invention comprises commercially available Baytron P VP AI1083 to which is added extra PSS which has a molecular weight of 27.3 kDa, ethylene glycol and an alcohol ether additive.

### Device Manufacturing Procedure

The procedure follows the steps outlined below:

1) Depositing a PEDT/PSS composition according to the present invention onto indium tin oxide supported on a glass substrate (available from Applied Films, Colorado, USA) by spin coating.

2) Depositing a layer of hole transporting polymer by spin coating from xylene solution having a concentration of 2% w/v.

3) Heating the layer of hole transport material in an inert (nitrogen) environment.

4) Optionally spin-rinsing the substrate in xylene to remove any remaining soluble hole transport material.

5) Depositing an organic light-emissive material comprising a host material and an organic phosphorescent material by spin-coating from xylene solution.

6) Depositing a metal compound/conductive material bi-layer cathode over the organic light-emissive material and encapsulating the device using an airtight metal enclosure available from Saes Getters SpA.

### Full Colour Display Manufacturing Procedure

A full colour display can be formed according to the process described in EP 0880303 by forming wells for red, green and blue subpixels using standard lithographical techniques; inkjet printing PEDT/PSS into each subpixel well; inkjet printing hole transport material; and inkjet printing red, green and blue electroluminescent materials into wells for red, green and blue subpixels respectively. As an alternative to printing into wells, a display may also be formed by printing into channels as disclosed in, for example, Carter et al, Proceedings of SPIE Vol. 4800, p. 34.

### EXAMPLES

### 1. Formulations and Ink Viscosity

Formulations set out below were all made using a 1:6 PEDOT:PSS formulation commercially available from H C Starck as Baytron P AI4083.

1:10 PEDOT:PSS formulations made by adding extra PSS to Baytron AI4083 in which the extra PSS has a molecular weight of 70 kDa gives an ink viscosity of greater than 10 mPa·s. This leads to jetting problems. Table 1 below shows the viscosities of various ink formulations.

TABLE 1

| Example | Formulation | Solvent | PSS | Viscosity |
|---|---|---|---|---|
| Com- | 1-10 PEDT- | 30% glycerol | 70 kDa | 10.35 mPa · s |
| parative | PSS 0.8% | | | |
| Example 1 | solids | | | |
| Example 1 | 1-10 PEDT- | 30% glycerol | 27.3 kDa | 7.8 mPa · s |
| | PSS 0.8% | | | |
| | solids | | | |
| Com- | 1-10 PEDT- | 27.5% | 70 kDa | 9.3 mPa · s |
| parative | PSS 0.8% | glycerol | | |
| Example 2 | solids | | | |
| Com- | 1-10 PEDT- | 25% glycerol | 70 kDa | 8.4 mPa · s |
| parative | PSS 0.8% | | | |
| Example 3 | solids | | | |
| Example 3 | 1-10 PEDT- | 27.5% | 27.3 kDa | 7.1 mPa · s |
| | PSS 0.8% | glycerol | | |
| | solids | | | |

It will be seen that, in order to achieve a viscosity which is below 10 mPa·s, either a low a molecular weight PSS or a lower amount of glycerol may be used. Reduction of the amount of glycerol can result in problems with swathes or highly domed films. These problems do not arise with lower molecular weight PSS.

### 2. Jetting Performance

Jetting performance was measured using a Litrex 80 L printer with Dimatix SX3 head (128 nozzles). Ink was degassed under vacuum and using ultrasonication for 30 minutes prior to the ink being put on the printer. The head was flushed with at least 10 ml of ink and then left to equilibrate for one hour prior to testing. The drop velocity was adjusted to obtain ligament length of <300 microns and at this drop velocity the drop directionality was measured as a function of frequency and time.

The drop directionality at 2 kHz was measured at zero minutes and after 30 minutes continuous jetting. Drop directionality is measured across the whole head (for all 128 nozzles). The drop directionality is measured by assessing the drop position at two points, the drop image being obtained using a strobe and camera set up. Each individual measurement is an average of the directionality of 10 drops.

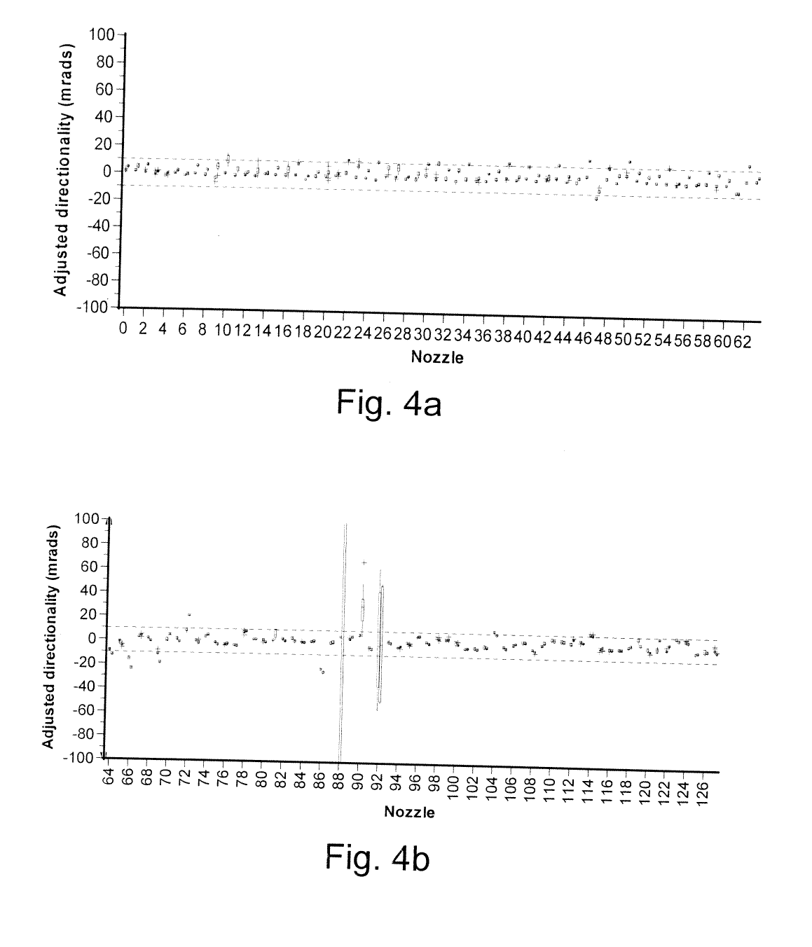

FIG. 4a shows the jetting directionality of the composition of Example 1 at both 0 and 30 minutes. It can be seen that the directionality is excellent, with virtually all nozzles printing within a very narrow window of ±10 mrads at both time=0 and after 30 minutes.

FIG. 4b shows the jetting directionality of the composition of comparative Example 1. It can be seen that the directionality is poor; data points falling outside the window arise at both t=0 and 30 minutes.

| | PSS Mw | Viscosity/cP | Viscosity/cP |
|---|---|---|---|
| Example | (×1000) | at 0 s⁻¹ | at 1000 s⁻¹ |
| Example 1 | 27.3 | 9.089 | 6.964 |
| | (PD201) | | |
| Comparative | 70 | 13.36 | 9.593 |
| Example 1 | (PD200) | | |
| Comparative | 211 | 19.20 | 13.44 |
| Example 2 | (PD203) | | |

1. A method for the manufacture of an organic light-emissive display comprising:
providing a substrate comprising a first electrode layer and a bank structure defining a plurality of wells;
depositing a conductive organic layer over the first electrode;
depositing an organic light-emissive layer over the conductive organic layer; and
depositing a second electrode over the organic light-emissive layer,
wherein the conductive organic layer is deposited by ink jet printing a composition comprising poly(ethylene dioxythiophene) (PEDOT) doped with a polyanion, wherein the polyanion has a molecular weight of less than 70 kDa measured relative to polystyrene molecular weight standards using gel-permeation chromatography.

2. A method according to claim 1, wherein the molecular weight of the polyanion is equal to or less than 30 kDa.

3. A method according to claim 1, the viscosity of the composition being equal to or less than 10 mPa·s.

4. A method according to claim 1, the solids content of the composition begs being equal to or less than 5 wt % based on the volume of the composition.

5. A method according to claim 4, wherein the solids content of the composition is in the range of from 0.1 wt % to 3 wt % based on the volume of the composition.

6. A method according to claim 1, wherein the polyanion is polystyrene sulfonate (PSS).

7. A method according to claim 6, wherein the weight ratio of PEDOT:PSS in the composition is in the range of from 1:2.5 to 1:40.

8. A method according to claim 7, wherein the weight ratio of PEDOT:PSS in the composition is in the range of from 1:6 to 1:18.

9. A composition being used to ink jet print an opto-electrical device, which composition comprises a charge transporting organic material which comprises poly(ethylene dioxythiophene) (PEDOT) doped with a polyanion, wherein the polyanion has a molecular weight of less than 70 kDa measured relative to polystyrene molecular weight standards using gel-permeation chromatography.

10. A composition according to claim 9, wherein the molecular weight of the polyanion is equal to or less than 30 kDa.

11. A composition according to claim 9 having a viscosity of less than or equal to 10 mPa·s.

12. A composition according to claim 9, the solids content of which is up to 5 wt % based on the volume of the composition.

13. A composition according to claim 12, wherein the solids content is in the range of from 0.1 wt % to 3 wt % based on the volume of the composition.

14. A composition according to claim 9, wherein the polyanion is polystyrene sulfonate (PSS).

15. A composition according to claim 14, wherein the weight ratio of PEDOT:PSS in the composition is in the range of from 1:6 to 1:18.
